(19) United States
(12) Patent Application Publication
(10) Pub. No.: US 2023/0307885 A1
(43) Pub. Date: Sep. 28, 2023

(54) LIGHT EMITTING ELEMENT, LIGHT EMITTING ELEMENT ARRAY, LIGHT EMITTING COMPONENT, OPTICAL DEVICE, AND OPTICAL MEASUREMENT APPARATUS

(71) Applicant: FUJIFILM Business Innovation Corp., Tokyo (JP)

(72) Inventors: Takashi KONDO, Kanagawa (JP); Michiaki MURATA, Kanagawa (JP); Takafumi HIGUCHI, Kanagawa (JP)

(73) Assignee: FUJIFILM Business Innovation Corp., Tokyo (JP)

(21) Appl. No.: 17/951,134

(22) Filed: Sep. 23, 2022

(30) Foreign Application Priority Data
Mar. 28, 2022 (JP) 2022-052355

(51) Int. Cl. H01S 5/042; G01S 17/08; G01S 7/481; H01S 5/40

(52) U.S. Cl. CPC H01S 5/04252; G01S 17/08; G01S 7/4814; H01S 5/40

(57) ABSTRACT

A light emitting element includes: a substrate; a light emitting unit that is laminated on the substrate; and a thyristor that is laminated on the light emitting unit and performs setting so as to cause the light emitting unit to emit light or increase an amount of emitted light by being turned into an ON state, the thyristor having a low resistance layer with a resistance which does not electrically separate the thyristor at a position where a current flows from an electrode being in contact with the thyristor.

### CROSS-REFERENCE TO RELATED APPLICATIONS

This application is based on and claims priority under 35 USC 119 from Japanese Patent Application No. 2022-052355 filed Mar. 28, 2022.

### BACKGROUND

### (i) Technical Field

The present invention relates to a light emitting element, a light emitting element array, a light emitting component, an optical device, and an optical measurement apparatus.

### (ii) Related Art

JP2020-120018A discloses a light emitting device capable of increasing a light output by suppressing deterioration in light emitting characteristics as compared with a case of increasing a size of a light emission point of the light emitting element.

Further, JP2000-294872A discloses an oxidized surface-emitting laser and a surface-emitting laser array, which have a simple fabrication process, are resistant to stress, and are highly reliable.

### SUMMARY

In the related, there is known a light emitting element in which a thyristor that performs setting so as to cause the light emitting unit to emit light or increase an amount of emitted light by being turned into an ON state by turning on the light emitting unit is laminated on the light emitting unit that emits light.

Here, depending on a resistance of a layer in which a current flows from the electrode being in contact with the thyristor, it is difficult for the current to flow in the lateral direction of the thyristor. As a result, the thyristor is electrically separated. In a case where the thyristor is electrically separated, unevenness and lighting deviation may occur in the light emission of the light emitting element, which is not appropriate.

Therefore, aspects of non-limiting embodiments of the present disclosure relate to a light emitting element that prevents the thyristor from being electrically separated in a case where the thyristor is laminated on the light emitting unit.

Aspects of certain non-limiting embodiments of the present disclosure overcome the above disadvantages and/or other disadvantages not described above. However, aspects of the non-limiting embodiments are not required to overcome the disadvantages described above, and aspects of the non-limiting embodiments of the present disclosure may not overcome any of the disadvantages described above.

According to an aspect of the present disclosure, there is provided a light emitting element comprising: a substrate; a light emitting unit that is laminated on the substrate; and a thyristor that is laminated on the light emitting unit and performs setting so as to cause the light emitting unit to emit light or increase an amount of emitted light by being turned into an ON state, the thyristor having a low resistance layer with a resistance which does not electrically separate the thyristor at a position where a current flows from an electrode being in contact with the thyristor.

### BRIEF DESCRIPTION OF THE DRAWINGS

Exemplary embodiment(s) of the present invention will be described in detail based on the following figures, wherein:

FIG. 1 is an equivalent circuit diagram of a light emitting component;

FIG. 2 is a diagram showing an example of a planar layout of the light emitting component;

FIG. 3 is a cross-sectional view taken along the line A-A of FIG. 2;

FIG. 4 is a cross-sectional view taken along the line B-B of FIG. 2;

FIG. 5 is a first explanatory diagram showing another structure of LD/S11 in the cross-sectional view taken along the line A-A of FIG. 2;

FIG. 6 is a second explanatory diagram showing another structure of LD/S11 in the cross-sectional view taken along the line A-A of FIG. 2;

FIG. 7 is a first explanatory diagram showing a method of manufacturing a transfer thyristor T1;

FIG. 8 is a second explanatory diagram showing a method of manufacturing the transfer thyristor T1;

FIG. 9 is a third explanatory diagram showing a method of manufacturing the transfer thyristor T1;

FIG. 10 is a schematic diagram showing a configuration of an optical device;

FIG. 11 is a schematic diagram showing a configuration of an optical measurement apparatus comprising the optical device; and

FIG. 12 is a diagram showing a state where light is emitted from the optical measurement apparatus.

### DETAILED DESCRIPTION

Hereinafter, referring to the accompanying drawings, the present exemplary embodiment will be described.

### First Exemplary Embodiment

First, the first exemplary embodiment will be described.

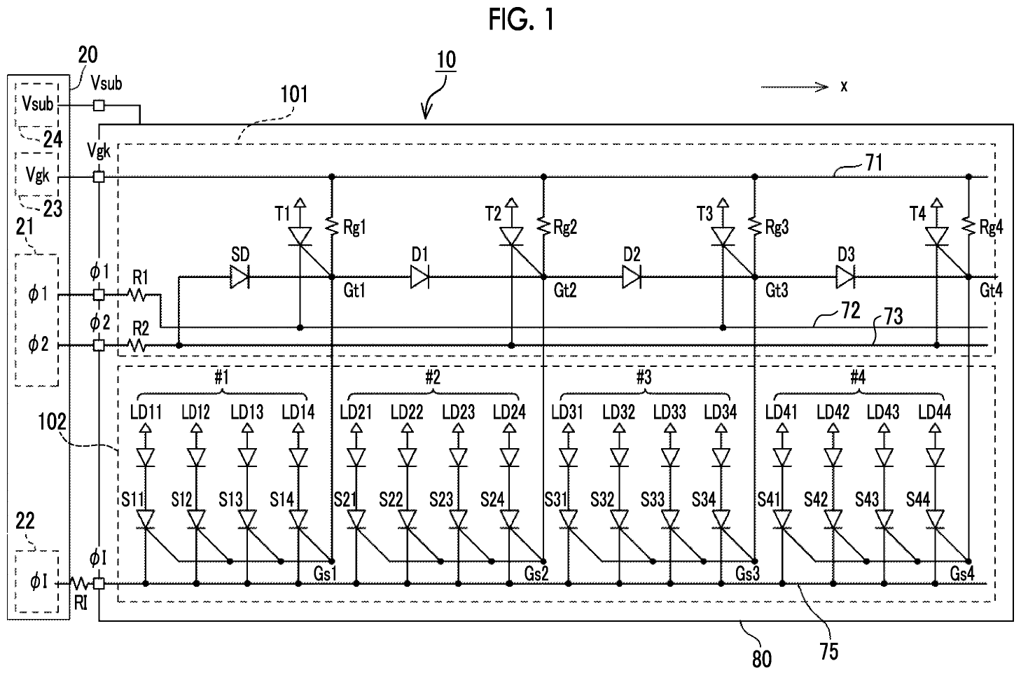

FIG. 1 is an equivalent circuit diagram of a light emitting component 10. Here, a control unit 20 that controls the light emitting component 10 is also shown. In FIG. 1, a left-right direction is the x direction.

The light emitting component 10 comprises a plurality of laser diodes LDs that emit laser light. The light emitting component 10 is configured as a self-scanning light emitting element array (SLED: Self-Scanning Light Emitting Device) to be described below. The laser diode LD is, for example, a vertical cavity surface emitting laser (VCSEL). Hereinafter, the light emitting element will be described as a laser diode LD. However, other light emitting devices such as a light emitting diode LED may be used.

The light emitting component 10 comprises a plurality of laser diode LD groups, each of which comprises a plurality of laser diodes LD. In FIG. 1, it is assumed that each laser diode LD group comprises four laser diodes LD as an example. In the following, the laser diode LD group will be referred to as laser diode LD group #1, #2, #3, . . . . In a case where each laser diode LD group is not distinguished, the laser diode LD group is referred to as a laser diode LD group or a laser diode LD group i (i is an integer of 1 or more). Although FIG. 1 shows four laser diode LD groups, the number of laser diode LD groups may be other than four.

The light emitting component 10 comprises a setting thyristor S for each laser diode LD. The laser diode LD and a setting thyristor S are connected in series.

Here, laser diodes LD belonging to the laser diode LD group #1 are referred to as laser diodes LD11 to 14. Here, in a case where the laser diode LDij (j is an integer of 1 or more) is represented, “i” is the number of the laser diode LD group, and “j” is the number of the laser diode LD in the laser diode LD group. The same reference numerals are given to the setting thyristors S. That is, the setting thyristor S included in the laser diode LD11 is referred to as a setting thyristor S11. In the example shown in FIG. 1, j is a number of 1 to 4. In FIG. 1, each laser diode LD group comprises the same number of laser diodes LD, but the number of laser diodes LD may differ between the laser diode LD groups. Further, the number of laser diodes LD in each laser diode LD group may be 2 or more.

In the present specification, the term “to” indicates a plurality of constituent elements, each of which is distinguished by a number, and means that the constituent elements described before and after “to” and the constituent elements having numbers therebetween are included. For example, the laser diodes LD11 to 14 include the laser diode LD11, the laser diode LD12, the laser diode LD13, and the laser diode LD14 in numerical order.

The light emitting component 10 further comprises a plurality of transfer thyristors T, a plurality of coupling diodes D, a plurality of power line resistors Rg, a start diode SD, and current-limiting resistors R1 and R2. Here, in a case of distinguishing a plurality of transfer thyristors T, the transfer thyristors T are numbered and distinguished, such as transfer thyristors T1, T2, T3, . . . . The same applies to the coupling diodes D and the power line resistors Rg. As will be described later, the transfer thyristor T1 is provided to correspond to the laser diode LD group #1. Therefore, in a case where the transfer thyristor T is represented as the transfer thyristor Ti, i corresponds to the same laser diode LD group. Accordingly, the transfer thyristor T may be referred to as a transfer thyristor Ti. The same applies to the coupling diodes D and the power line resistors Rg.

The number of transfer thyristors T in the light emitting component 10 may be a predetermined number. For example, the number may be 128, 512, or 1024. FIG. 1 shows a part corresponding to the transfer thyristors T1 to T4. The number of transfer thyristors T may be the same as the number of laser diode LD groups, may be greater than the number of laser diode LD groups, or may be small.

The transfer thyristors T are arranged in the x direction in order of transfer thyristors T1, T2, T3, . . . . The coupling diodes D are arranged in the x direction in order of the coupling diodes D1, D2, D3, . . . . The coupling diode D1 is provided between the transfer thyristor T1 and the transfer thyristor T2. The same applies to the other coupling diodes D. Further, the power line resistors Rg are also arranged in the x direction in order of the power line resistors Rg1, Rg2, Rg3, . . . .

The laser diode LD and the coupling diode D are two-terminal elements each comprising an anode and a cathode. The setting thyristor S and the transfer thyristor T are three-terminal elements each comprising an anode, a cathode, and a gate. The gate of the transfer thyristor T is referred to as a gate Gt, and the gate of the setting thyristor S is referred to as a gate Gs. In addition, in a case of distinguishing each gate, i is added in the same manner as described above.

Here, a part composed of the laser diodes LD and the setting thyristors S is set as a light emitter 102, and a part composed of the transfer thyristors T, the coupling diodes D, the start diode SD, the power line resistors Rg, and the current-limiting resistors R1 and R2 is set as a transfer unit 101.

Next, the connection relationship of each element (laser diode LD, setting thyristor S, transfer thyristor T, and the like) will be described.

As described above, the laser diodes LDij and the setting thyristors Sij are connected in series. That is, in the laser diode LD, the anode is connected to a reference potential Vsub (ground potential (GND) or the like), and the cathode is connected to the anode of the setting thyristor Sij.

Here, in the light emitting component 10, the setting thyristors S are laminated on the laser diodes LD. Hereinafter, the semiconductor layer laminate of the laser diode LD and the setting thyristor S will be referred to as “LD/S”. Further, the laser diode LD, which belongs to each laser diode LD group, and the setting thyristor S, which is provided for each laser diode LD, are collectively referred to as an “LD/S group”. The LD/S is an example of the “light emitting element”, and the LD/S group is an example of the “light emitting element group”.

The cathode of the setting thyristor Sij is commonly connected to a lighting signal line 75 that supplies a lighting signal φI for controlling the laser diode LD such that the laser diode LD is in a light emitting or non-light emitting state.

As will be described later, the reference potential Vsub is supplied via an electrode (not shown) provided on a rear surface of a GaAs substrate 80 constituting the light emitting component 10.

In the transfer thyristor T, the anode thereof is connected to the reference potential Vsub. The cathodes of the odd-numbered transfer thyristors T1, T3, . . . are connected to a transfer signal line 72. The transfer signal line 72 is connected to a φ1 terminal via the current-limiting resistor R1.

The cathodes of the even-numbered transfer thyristors T2, T4, . . . are connected to a transfer signal line 73. The transfer signal line 73 is connected to a φ2 terminal via the current-limiting resistor R2.

The coupling diodes D are connected with each other in series. That is, the cathode of one coupling diode D is connected to the anode of the coupling diode D which is adjacent in the x direction. In the start diode SD, the anode is connected to the transfer signal line 73, and the cathode is connected to the anode of the coupling diode D1.

Then, the cathode of the start diode SD and the anode of the coupling diode D1 are connected to a gate Gt1 of the transfer thyristor T1. The cathode of the coupling diode D1 and the anode of the coupling diode D2 are connected to a gate Gt2 of the transfer thyristor T2. The same applies to the other coupling diode D.

The gate Gt of the transfer thyristor T is connected to a power line 71 via the power line resistor Rg. The power line 71 is connected to a Vgk terminal.

A gate Gti of the transfer thyristor T1 is connected to a gate Gsi of the setting thyristor Sij.

A configuration of the control unit 20 will be described.

The control unit 20 generates a signal such as a lighting signal φI and supplies the signal to the light emitting component 10. The light emitting component 10 operates in response to the supplied signal. The control unit 20 is composed of an electronic circuit. For example, the control unit 20 may be an integrated circuit (IC) configured to drive the light emitting component 10.

The control unit 20 comprises a transfer signal generation unit 21, a lighting signal generation unit 22, a power source potential generation unit 23, and a reference potential generation unit 24.

The transfer signal generation unit 21 generates transfer signals φ1 and φ2 so as to supply the transfer signal 41 to the 41 terminal of the light emitting component 10 and supply the transfer signal φ2 to the φ2 terminal of the light emitting component 10. The transfer signals φ1 and φ2 are signals which are “H (0V)” or “L (−3.3V)”. 0V is a potential for turning off the transfer thyristor T, and −3.3V is a potential for turning the transfer thyristor T from an OFF state to an ON state.

The lighting signal generation unit 22 generates the lighting signal φI and supplies the signal to a φI terminal of the light emitting component 10 via a current-limiting resistor RI. The lighting signal φI is a signal which is “H (0V)” or “L (−3.3V)”. 0V is a potential for turning off the laser diode LD, and −3.3V is a potential for turning the laser diode LD from the OFF state to the ON state. The current-limiting resistor RI may be provided in the light emitting component 10. Further, in a case where the current-limiting resistor RI is not necessary for an operation of the light emitting component 10, the current-limiting resistor RI does not have to be provided.

The power source potential generation unit 23 generates a power source potential Vgk to supply the potential to the Vgk terminal of the light emitting component 10. The reference potential generation unit 24 generates a reference potential Vsub to supply the potential to the Vsub terminal of the light emitting component 10. The power source potential Vgk is, for example, −3.3V. As described above, the reference potential Vsub is a ground potential (GND) as an example.

In the light emitting component 10 shown in FIG. 1, four laser diodes LDij (j=1 to 4) are connected to one transfer thyristor T1 via the setting thyristors Sij, respectively.

The transfer thyristor Ti sets each LD/S group of the plurality of LD/S groups such that a lighting state or a non-lighting state propagates in sequence. Specifically, in a case where the transfer thyristor Ti is turned on, the setting thyristor Sij connected to the transfer thyristor Ti is set so as to be able to shift to the ON state. Thereby, the setting thyristor Sij provided in the LD/S of each LD/S group of the plurality of LD/S groups is turned on at different time in each LD/S group. The transfer thyristor Ti is driven such that the ON state propagates. Therefore, the transfer thyristor Ti is referred to as a transfer thyristor T. In addition, in a case where the setting thyristor Sij is turned on, the laser diode LDij emits light. Therefore, since the laser diode LD is set to be capable of emitting light, a thyristor for the setting is referred to as a setting thyristor S.

Here, the plurality of LD/S groups are configured, the LD/S group is connected to each transfer thyristor T, and the laser diode LD belonging to the LD/S group emits light in parallel.

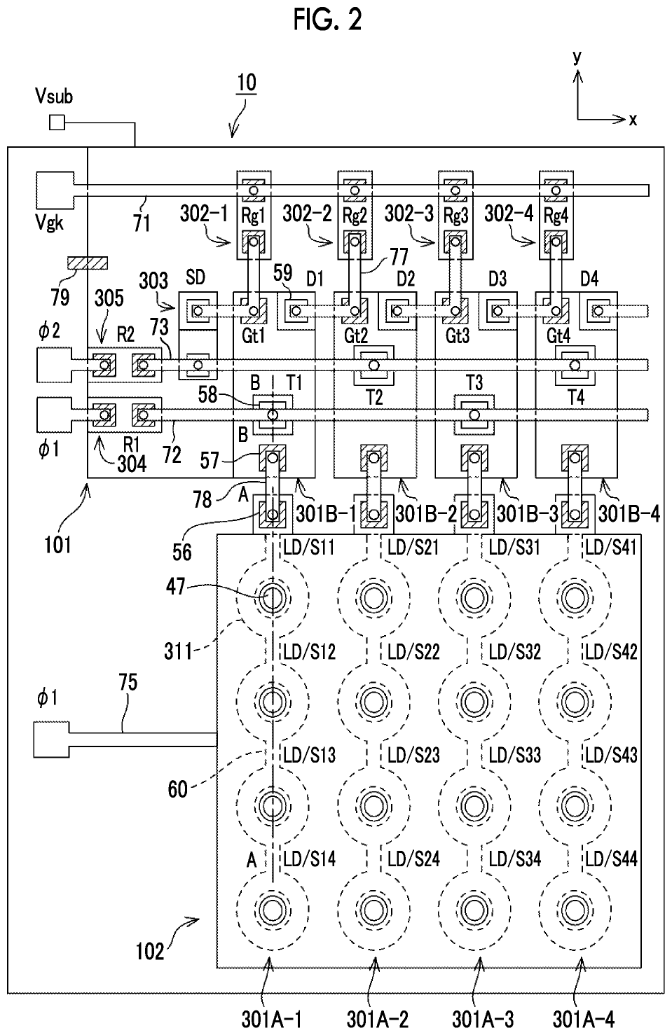

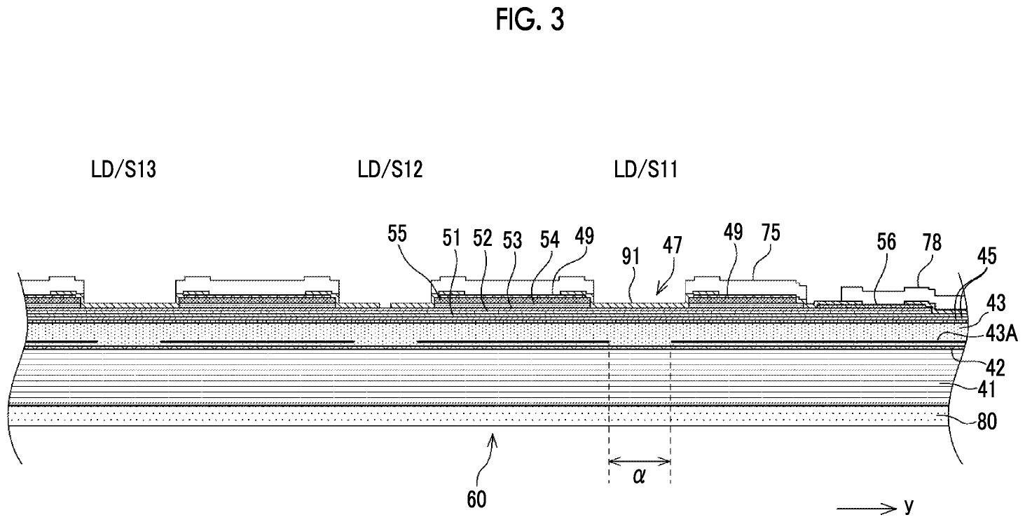

The laser diode LD may oscillate in, for example, a low-order single transverse mode (single mode). In the single mode, an intensity profile of the light (emitted light) emitted from a light emission point of the laser diode LD (light emission opening 47 in FIGS. 2 and 3 to be described later) is unimodal (characteristic of having one intensity peak). On the other hand, in the laser diode LD that oscillates in the multiple transverse mode (multi mode) including high order, the intensity profile tends to have distortion such as multiple peaks. Further, in the single mode, a spread angle of the light emitted from the light emission point (emitted light) is smaller than a spread angle in the multi mode. Therefore, in a case where the light output is the same, the single mode has a higher light density on an irradiated surface than the multi mode. The spread angle means a full width at a half maximum (FWHM) of the light emitted from the laser diode LD.

The smaller the area of the light emission point, the easier it is for the laser diode LD to oscillate in the single transverse mode (single mode). Therefore, the single mode laser diode LD has a small light output. In a case where the area of the light emission point is increased in an attempt to increase the light output, the mode shifts to the multi-mode as described above. Therefore, in the first exemplary embodiment, the plurality of laser diodes LD are designated as the laser diode LD group, and the plurality of laser diodes LD included in the laser diode LD group are made to emit light in parallel to increase the light output.

FIG. 2 is a diagram showing an example of a planar layout of the light emitting component 10. On the page of FIG. 2, the left-right direction is the x direction and the up-down direction is the y direction. The x direction is the same as the x direction in FIG. 1. In FIG. 2, the light emitter 102 is a light emitting element array in which the plurality of LD/S groups each having the plurality of LD/S are arranged.

The light emitting component 10 is composed of a semiconductor material capable of emitting laser light. For example, the light emitting component 10 is composed of a GaAs-based compound semiconductor. Then, as shown in a cross-sectional view (refer to FIG. 3) to be described later, the light emitting component 10 is composed of a semiconductor layer laminate in which a plurality of GaAs-based compound semiconductor layers are laminated on a p-type GaAs substrate 80. Further, the light emitting component 10 is configured by separating the semiconductor layer laminate into a plurality of island-shaped pieces. A region left in the island shape is referred to as an island. Etching the semiconductor layer laminate in island shapes to separate the elements is called mesa etching. Here, the planar layout of the light emitting component 10 will be described with reference to islands 301, 302, 303, 304, and 305 shown in FIG. 2. In a case where the islands 301 and 302 are distinguished from each other, the islands 301 and 302 are represented as islands 301-i or 302-i (i≥1) as described above. The island 301 is separated into an island 301A in which the LD/S group is provided and an island 301B in which the transfer thyristor T and the coupling diode D are provided.

The island 301A-i is provided with the laser diode LDij and the setting thyristor Sij, and the island 301B-i is provided with the transfer thyristor T1 and the coupling diode Di (in this example, j=1 to 4). Then, in the islands 301A-i, posts 311, each of which is configured in a cylinder shape in accordance with an outer shape of the laser diode LD, are arranged. The post 311 is a part of the LD/S from which laser light is emitted.

A part of each post 311 belonging to each LD/S group is continuous in the y direction at the facing part. Hereinafter, a part in which a part of each post 311 is continuous in the y direction is referred to as a “connection part 60”. That is, the setting thyristor S provided in each of the plurality of LD/Ss are connected via the connection part 60. In FIG. 2, each LD/S is described as LD/Sij to distinguish LD/S.

Further, the islands 301A-i are provided to be parallel to each other in the x direction. Here, the LD/S groups are one-dimensionally arranged in the x direction.

The island 302-i is provided with a power line resistor Rgi. The islands 302-i are provided to be parallel to each other in the x direction.

The island 303 is provided with the start diode SD. The island 304 is provided with the current-limiting resistor R1, and the island 305 is provided with the current-limiting resistor R2.

FIG. 3 is a cross-sectional view taken along the line A-A of FIG. 2. In FIG. 3, the left-right direction is the y direction.

FIG. 3 shows LD/S13, LD/S12, and LD/S11 from the left. Since a structure of each LD/S is common, LD/S11 will be described as an example.

As shown in FIG. 3, the LD/S11 has a structure in which the laser diode LD that generates the laser light and the setting thyristor S that controls the lighting and extinguishing of the laser diode LD are combined with a tunnel cementing layer 45 interposed therebetween on the GaAs substrate 80 which is a compound semiconductor substrate. The GaAs substrate 80 is an example of the “substrate”, the laser diode LD is an example of the “light emitting unit”, and the setting thyristor S is an example of the “thyristor”.

In the laser diode LD, an n-type cathode layer 41, a light emitting layer 42, and a p-type anode layer 43 are laminated on the GaAs substrate 80. The light emitting layer 42 has a quantum well structure in which well layers and barrier layers are alternately laminated.

A part of the anode layer 43 is formed with a current constriction layer 43A generated by oxidation. The current constriction layer 43A is formed such that current flowing through the LD/S11 passes through the central part by constricting a current path of the current flowing through the LD/S11. Specifically, the central part of the current constriction layer 43A is formed as a current pass region a in which current easily flows, and a peripheral portion thereof is formed as a current block region in which current does not easily flow.

By providing such a current constriction layer 43A, power consumed for non-luminescence recombination is suppressed, and power consumption is reduced and a light emission efficiency is increased.

Here, the current constriction layer 43A is formed by oxidizing a part of the anode layer 43 as described above. It should be noted that oxidizing a part of the anode layer 43 to form the current constriction layer 43A may be referred to as oxidization constriction.

Then, the tunnel cementing layer 45 is laminated on the anode layer 43. The tunnel cementing layer 45 is configured by cementing an n⁺⁺ layer in which n-type impurities are added at a high concentration and a p⁺⁺ layer in which p-type impurities are added at a high concentration. The n⁺⁺ layer and the p⁺⁺ layer each have a high impurity concentration of, for example, 1×10²¹/cm³.

The setting thyristor S is laminated on the tunnel cementing layer 45. The setting thyristor S is laminated in order of a cathode layer 51, a p-type p-gate layer 52, a n-type n-gate layer 53, an anode layer 54, and a low resistance layer 55.

The low resistance layer 55 is a p-type semiconductor layer in which p-type impurities are added at a high concentration. For example, the impurity concentration is 1×10¹⁹/cm³ or more and 1×10²¹/cm³ or less. The resistance of the low resistance layer 55 is lower than the resistance of the anode layer 54 and higher than the resistances of the p-gate layer 52 and the n-type n-gate layer 53.

Further, on the low resistance layer 55, an electrode 49 that supplies a current for controlling the ON state and an OFF state of the setting thyristor S is formed. The electrode 49 is made of a metal material such as the low resistance layer 55, which easily forms ohmic contact with a p-type semiconductor layer. In such a case, as shown in FIG. 3, the electrode 49 is disposed at the connection part 60 connecting each LD/S. The electrode 49 extends in the y direction in FIG. 3, and one electrode 49 is shared between LD/Ss, for example, LD/S11 and LD/S12. By sharing the electrodes 49 among the plurality of LD/Ss, the number of electrodes 49 included in the light emitter 102 is smaller than the number in a case where the electrode 49 is provided for each LD/S. The electrode 49 is an example of “an electrode being in contact with a thyristor” and “an electrode being in contact with a setting thyristor”.

Further, an interlayer insulating layer 91 is provided to cover the entire light emitting component 10. The lighting signal line 75 is provided on the interlayer insulating layer 91 so as to be connected to the electrode 49 via a through-hole provided in the interlayer insulating layer 91. The lighting signal line 75 is an example of the “supply electrode”.

Here, a signal for controlling the ON state and the OFF state of the setting thyristor S is supplied to the electrode 49.

The lighting signal line 75 supplies a current for light emission to the laser diode LD. More specifically, the lighting signal line 75 supplies a current to the electrode 49 of the laser diode LD via a through-hole provided in the interlayer insulating layer 91. The lighting signal line 75 has an area larger than an area of the electrode 49. Thereby, the lighting signal line 75 is able to flow a current larger than, for example, a current in a case where a current flows to the electrode 49.

In a case where the interlayer insulating layer 91 is inferior in translucency to the emitted light of the laser diode LD, instead of the interlayer insulating layer 91, the light exit layer, which is excellent in translucency of the emitted light of the laser diode LD, may be provided on the light emission opening 47.

An electrode 56 is provided on the exposed n-gate layer 53 except for the low resistance layer 55 and the anode layer 54, on the right side of the LD/S 11 in FIG. 3. The electrode 56 is connected to the wiring line 78 via a through-hole provided in the interlayer insulating layer 91.

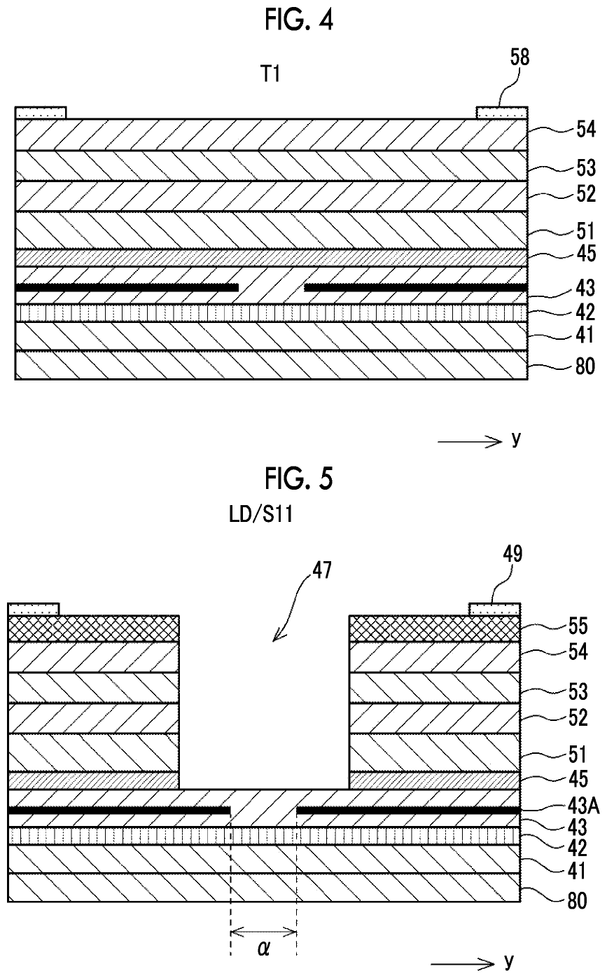

FIG. 4 is a cross-sectional view taken along the line B-B of FIG. 2. In FIG. 4, the left-right direction is the y direction.

In the transfer thyristor T1, the cathode layer 41, the light emitting layer 42, the anode layer 43, the tunnel cementing layer 45, the cathode layer 51, the p-gate layer 52, the n-gate layer 53, and the anode layer 54 are laminated on the GaAs substrate 80. Consequently, unlike the LD/S11, the transfer thyristor T1 is not provided with the low resistance layer 55.

The transfer thyristor T1 is provided with the electrode 58 on the anode layer 54 and functions as a gate for controlling the operation of the transfer thyristor T1. The electrode 58 is connected to the transfer signal line 72 (refer to FIG. 2). The electrode 58 is an example of the “electrode being in contact with the transfer thyristor”.

Although not shown, an electrode 57 (refer to FIG. 2) is provided on the anode layer 54 on the left side of the transfer thyristor T1 in FIG. 4. The electrode 57 is connected to the wiring line 78 (refer to FIG. 2) via a through-hole provided in the interlayer insulating layer 91. In such a manner, in a case where the transfer thyristor T is turned on and the gate Gt is 0V, the gate Gs of the setting thyristor S is at 0V via the wiring line 78. Consequently, the ON state of the transfer thyristor T is transferred in order, such that the connected setting thyristor S shifts to the ON state.

Further, in a part where the transfer thyristor T1 is provided on the semiconductor layers (cathode layer 41, light emitting layer 42, and anode layer 43) constituting the laser diode LD, the cathode layer 41, the light emitting layer 42, and the anode layer 43 are shot-circuited through a wiring line 79 (refer to FIG. 2) such that the laser diode LD does not operate.

As described above, the light emitting component 10 uses the plurality of laser diodes LD as the laser diode LD group, and causes the plurality of laser diodes LD included in the laser diode LD group to emit light in parallel. In such a case, in a case where a wiring line for supplying a signal for controlling light emission or non-light emission of the laser diode LD is provided from the transfer unit 101 for each laser diode LD included in the laser diode LD group, a distance between the laser diodes LD has to be increased. Thus, an area of the light emitting component 10 increases.

Therefore, in the light emitting component 10, the setting thyristor S for setting the laser diode LD to be capable of emitting light is provided for each laser diode LD, and the setting thyristor S and the laser diode LD are laminated. Thereby, an increase in area of the light emitting component 10 is suppressed. Further, for each LD/S group, it is not necessary to provide a wiring line for supplying a signal for controlling light emission or non-light emission of the laser diode LD from the transfer unit 101 by connecting the semiconductor layer constituting the setting thyristor S by the connection part 60.

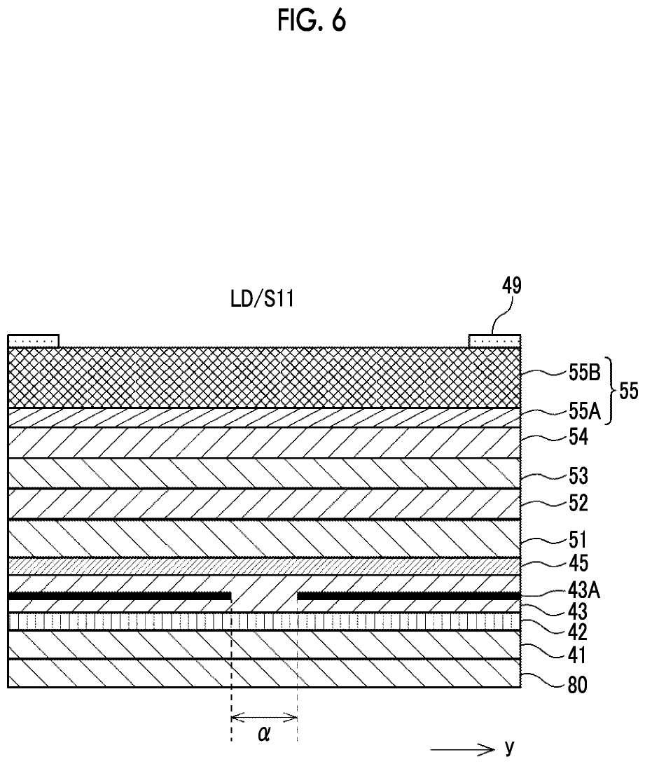

The structure of the LD/S in the cross-sectional view taken along the line A-A of FIG. 2 is not limited to that shown in FIG. 3. For example, the structure of the LD/S may be that shown in FIG. 5 or FIG. 6.

FIG. 5 is a first explanatory diagram showing another structure of LD/S11 in the cross-sectional view taken along the line A-A of FIG. 2. In FIG. 5, the left-right direction is the y direction. It should be noted that FIG. 5 is a schematic diagram in which the structure of the LD/S 11 is partially omitted.

Unlike the LD/S11 shown in FIG. 3, the LD/S11 shown in FIG. 5 has the setting thyristor S which is removed from the central portion of the LD/S11. That is, in the central portion of the LD/S11, the low resistance layer 55, the anode layer 54, the n-gate layer 53, the p-gate layer 52, the cathode layer 51, and the tunnel cementing layer 45 are removed by etching. Thereby, the anode layer 43 of the laser diode LD is exposed. In such a case, the exposed part of the anode layer 43 is the light emission opening 47 of the laser diode LD.

As described above, the LD/S may have a structure in which the tunnel cementing layer 45, the cathode layer 51, the p-gate layer 52, the n-gate layer 53, the anode layer 54, and the low resistance layer 55 remain such that the setting thyristor S is configured to surround the light emission opening 47 of the laser diode LD.

FIG. 6 is a second explanatory diagram showing another structure of LD/S11 in the cross-sectional view taken along the line A-A of FIG. 2. In FIG. 6, the left-right direction is the y direction. It should be noted that FIG. 6 is a schematic diagram in which the structure of the LD/S 11 is partially omitted.

In the LD/S11 shown in FIG. 6, the cathode layer 41, the light emitting layer 42, and the anode layer 43 are laminated on the GaAs substrate 80, in a similar manner to the LD/S11 shown in FIG. 3. Further, in the LD/S11 shown in FIG. 6, the tunnel cementing layer 45 is laminated on the anode layer 43 and the setting thyristor S is laminated on the tunnel cementing layer 45. However, the structure of the low resistance layer 55 included in the setting thyristor S is different from the structure of the LD/S11 shown in FIG. 3.

The low resistance layer 55 shown in FIG. 6 is composed of a tunnel cementing layer 55A and an n-type layer 55B.

The tunnel cementing layer 55A is configured by cementing an n⁺⁺ layer in which n-type impurities are added at a high concentration and a p⁺⁺ layer in which p-type impurities are added at a high concentration. The n⁺⁺ layer and the p⁺⁺ layer each have a high impurity concentration of, for example, 1×10²¹/cm³.

The n-type layer 55B is, for example, an n-type semiconductor layer having an impurity concentration of 1×10¹⁹/cm³. The n-type layer 55B is an example of the “n-type semiconductor layer”. In such a case, the anode layer 54 cemented to the n-type layer 55B via the tunnel cementing layer 55A is an example of “another layer of the thyristor”. With such a configuration, the LD/S is downsized as compared with the case where the n-type layer 55B and the anode layer 54 are not laminated.

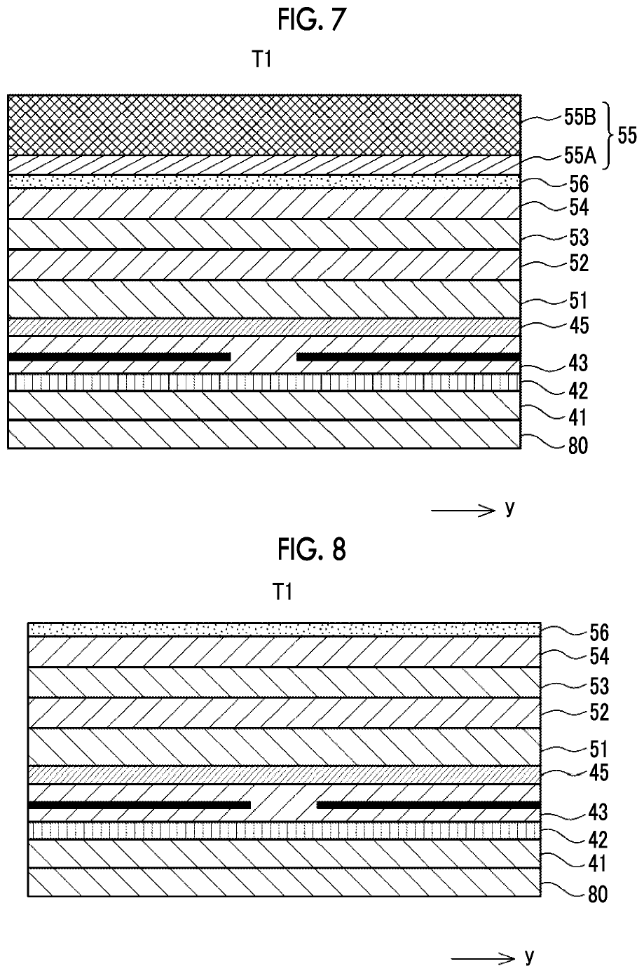

Next, a method of manufacturing the transfer thyristor T1 shown in FIG. 4 will be described with reference to FIGS. 7 to 9. In the following description, for example, it is assumed that the low resistance layer 55 of the LD/S is composed of the tunnel cementing layer 55A and the n-type layer 55B shown in FIG. 6.

In the transfer thyristor T1 shown in FIG. 7, the cathode layer 41, the light emitting layer 42, the anode layer 43, the tunnel cementing layer 45, the cathode layer 51, the p-gate layer 52, the n-gate layer 53, the anode layer 54, the GaInP layer 56, the tunnel cementing layer 55A, and the n-type layer 55B are laminated on the GaAs substrate 80.

The GaInP layer 56 is a semiconductor layer made of GaInP.

The transfer thyristor T1 shown in FIG. 8 shows a state after the tunnel cementing layer 55A and the n-type layer 55B have been removed by etching from the state shown in FIG. 7. In the etching of the tunnel cementing layer 55A and the n-type layer 55B, for example, a phosphoric acid system is used as an etchant.

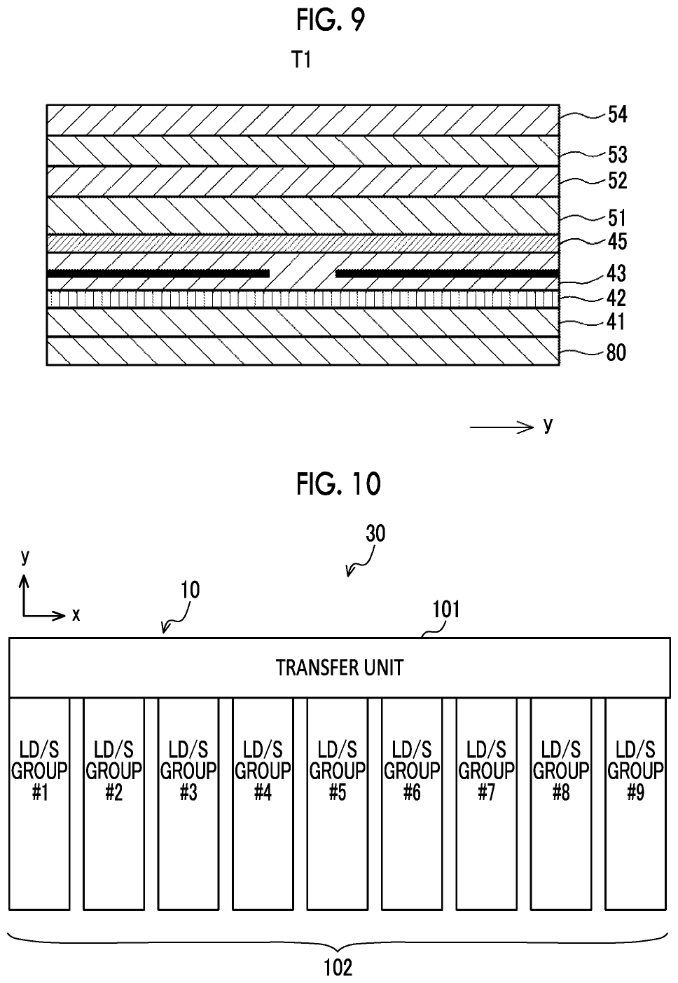

The transfer thyristor T1 shown in FIG. 9 shows a state after the GaInP layer 56 has been removed by etching from the state shown in FIG. 8. In the etching of the GaInP layer 56, for example, phosphoric acid or hydrochloric acid is used as an etchant.

By the above-described steps, in the transfer thyristor T1 shown in FIG. 9, the low resistance layer 55 and the GaInP layer 56 are removed, and the uppermost portion is the anode layer 54. Although not shown in FIG. 9, the electrode 58 is provided on the anode layer 54 (refer to FIG. 4). Thereby, in the transfer thyristor T1, the anode layer 54 is an example of “the layer through which the current flows from the electrode being in contact with the transfer thyristor”.

Here, unlike the setting thyristor S provided in the light emitter 102, a high resistance is necessary for the transfer thyristor T provided in the transfer unit 101. Therefore, a high resistance layer is provided on the uppermost portion. For example, the anode layer 54 is a p-type semiconductor layer that has an impurity concentration of 1×10¹⁸/cm³, and has a higher resistance than the low resistance layer 55. That is, the low resistance layer 55 of the setting thyristor S has a lower resistance than the anode layer 54 of the transfer thyristor T. With such a configuration, in the first exemplary embodiment, the operation of the transfer thyristor T can be stabilized as compared with a case where the anode layer 54 of the transfer thyristor T has a lower resistance than the low resistance layer 55 of the setting thyristor S.

In the above description, the case where the low resistance layer 55 and the GaInP layer 56 are removed has been described as a method of manufacturing the transfer thyristor T1. However, the present invention is not limited to this, and the transfer thyristor T1 does not have to be provided with the low resistance layer 55 in advance.

As described above, in the first exemplary embodiment, the LD/S comprises the GaAs substrate 80, the laser diode LD, and the setting thyristor S. In such a case, the setting thyristor S is provided with the low resistance layer 55 having a resistance that does not electrically separate the setting thyristor S at a position where a current from the electrode 49 flows. In the first exemplary embodiment, the low resistance layer 55 having a resistance that does not electrically separate the setting thyristor S is, for example, a p-type semiconductor layer having an impurity concentration of 1×10¹⁹/cm³ or more and 1×10²¹/cm³ or less or an n-type semiconductor layer having an impurity concentration of greater than 1×10¹⁸/cm³. In a case where the low resistance layer 55 is a p-type semiconductor layer, the structure of the low resistance layer 55 is simpler than a structure in a case where the low resistance layer 55 is an n-type semiconductor layer. Further, in a case where the low resistance layer 55 is an n-type semiconductor layer, the resistance of the low resistance layer 55 is lower than a resistance in a case where the low resistance layer 55 is a p-type semiconductor layer.

In the first exemplary embodiment, the low resistance layer 55 is provided on the uppermost portion of the setting thyristor S as a position where the current flows from the electrode 49. However, the present invention is not limited to this. For example, in a case of the position where the current flows from the electrode 49, the low resistance layer 55 may be provided in another layer such as a layer immediately below the uppermost portion of the setting thyristor S.

Here, in a case where the resistance of the low resistance layer 55 is higher than the above reference, it is difficult for a current to flow in the lateral direction of the setting thyristor S, and the setting thyristor S may be electrically separated. In a case where the setting thyristor S is electrically separated, unevenness and lighting deviation may occur in the light emission of the LD/S, which is not appropriate.

However, in the first exemplary embodiment, the low resistance layer 55 having a resistance lower than the above standard is adopted. Therefore, in a case where the setting thyristor S is laminated on the laser diode LD, the setting thyristor S can be made not to be electrically separated.

Further, in order not to electrically separate the setting thyristor S, it can be assumed that a circular electrode is provided to surround the light emission opening 47 on the uppermost portion of the setting thyristor S. However, in such a case, it is necessary to provide a margin, which is for providing the electrode, for the LD/S. As a result, the size of the LD/S increases. On the other hand, in the first exemplary embodiment, the circular electrode surrounding the light emission opening 47 is not provided on the uppermost portion of the setting thyristor S. Therefore, the LD/S can be miniaturized as compared with the case where the electrode is provided.

Further, in the first exemplary embodiment, a signal for controlling the ON state and the OFF state of the setting thyristor S is supplied to the electrode 49. Thereby, in the first exemplary embodiment, the ON state and the OFF state of the setting thyristor S are switched.

Further, in the first exemplary embodiment, the lighting signal line 75 that supplies a current for causing the laser diode LD to emit light is provided. Thereby, in the first exemplary embodiment, the laser diode LD emits light via the lighting signal line 75.

### Second Exemplary Embodiment

Next, a second exemplary embodiment will be described while omitting or simplifying an overlapping part with the other exemplary embodiments.

An optical device 30 in the second exemplary embodiment employs the light emitting component 10 described in the first exemplary embodiment.

FIG. 10 is a schematic diagram showing a configuration of the optical device 30. Then, the left-right direction is the x direction and the up-down direction is the y direction.

The optical device 30 comprises a light emitting component 10 and an optical element (not shown). The light emitting component 10 comprises nine LD/S groups (LD/S groups #1 to #9) and a transfer unit 101 one-dimensionally arranged in the x direction on the light emitter 102. The detailed description of the transfer unit 101 will not be repeated. Then, the optical device 30 comprises an optical element that sets a direction or a spread angle of the light emitted from each LD/S group in the plurality of LD/S groups included in the light emitting component 10 to a predetermined direction or a predetermined spread angle. Hereinafter, for example, a description will be given in a case where the optical element is a convex lens (hereinafter referred to as a lens LZ) and the emission direction of light is deflected in the predetermined direction. For example, the LD/S group #1 is disposed with the center of the lens LZ shifted in the x direction with respect to the center of the light emission opening 47 (refer to FIG. 3) of the laser diode LD so as to deflect the light emitted by the laser diode LD in the x direction.

In a case where the lens LZ is a small lens such as a micro lens, the deflection angle may be small. In such a case, another lens may be provided on the front surface of the optical device 30 provided with the lens LZ so as to increase the deflection angle. Further, the lens LZ has been described as a convex lens but may be a concave lens or an aspherical lens.

Further, in the above description, the emission direction of light is deflected, but the spread angle may be changed. For example, the convex lens may be employed to focus the light on the irradiated surface, or the light may be spread so as to be irradiated in a predetermined range on the irradiated surface.

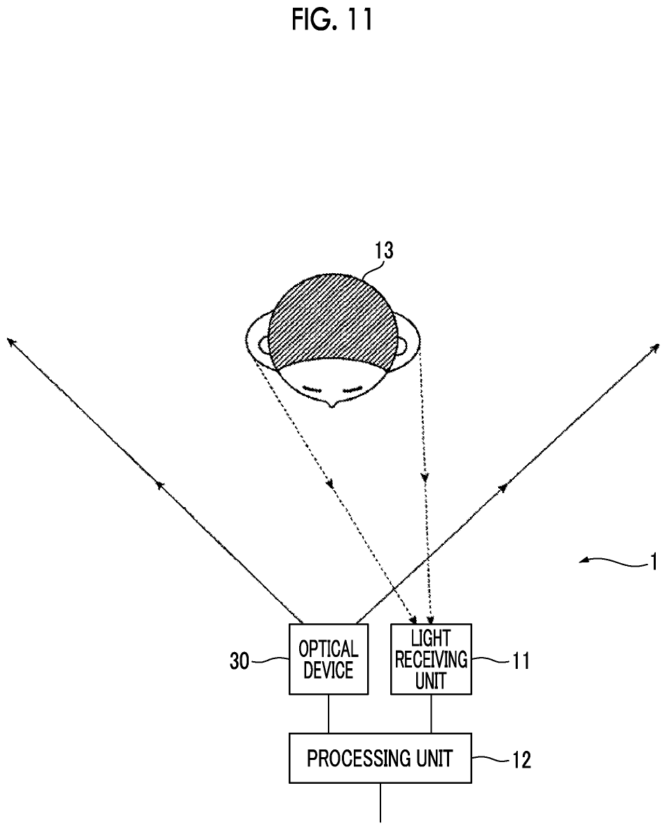

FIG. 11 is a schematic diagram showing a configuration of an optical measurement apparatus 1 comprising the optical device 30. The optical measurement apparatus 1 comprises an optical device 30, a light receiving unit 11 that receives reflected light from a measurement target object (target object) 13 irradiated with light from the optical device 30, and a processing unit 12 that processes information about the light received by the light receiving unit 11 so as to measure the distance from the optical device 30 to the measurement target object 13 or the shape of the measurement target object 13. Then, the measurement target object 13 is set to be close to the optical measurement apparatus 1. The measurement target object 13 is, for example, a human being. Then, FIG. 11 is a diagram viewed from above.

The light receiving unit 11 is a device that receives the light reflected by the measurement target object 13. The light receiving unit 11 may be a photodiode. The photodiode is, for example, a single photon avalanche diode (SPAD) that can accurately measure the light receiving time.

The processing unit 12 is configured as a computer including an input output unit for inputting and outputting data. Then, the processing unit 12 processes the information about the light so as to calculate the distance to the measurement target object 13 and the two-dimensional or three-dimensional shape of the measurement target object 13.

The processing unit 12 of the optical measurement apparatus 1 controls the light emitting component 10 of the optical device 30 so as to emit the light from the light emitting component 10. That is, the light emitting component 10 of the optical device 30 emits the light in a pulse shape. Then, the processing unit 12 calculates an optical path length until light is emitted from the optical device 30, then reflected by the measurement target object 13, and reaches the light receiving unit 11, on the basis of the time difference between the time at which the light emitting component 10 emits light and the time at which the light receiving unit 11 receives the reflected light from the measurement target object 13. Therefore, the processing unit 12 measures a distance from the optical device 30 and the light receiving unit 11 or a distance from a point serving as a reference (hereinafter referred to as the reference point) to the measurement target object 13. In addition, the reference point is a point provided at a predetermined position from the optical device 30 and the light receiving unit 11.

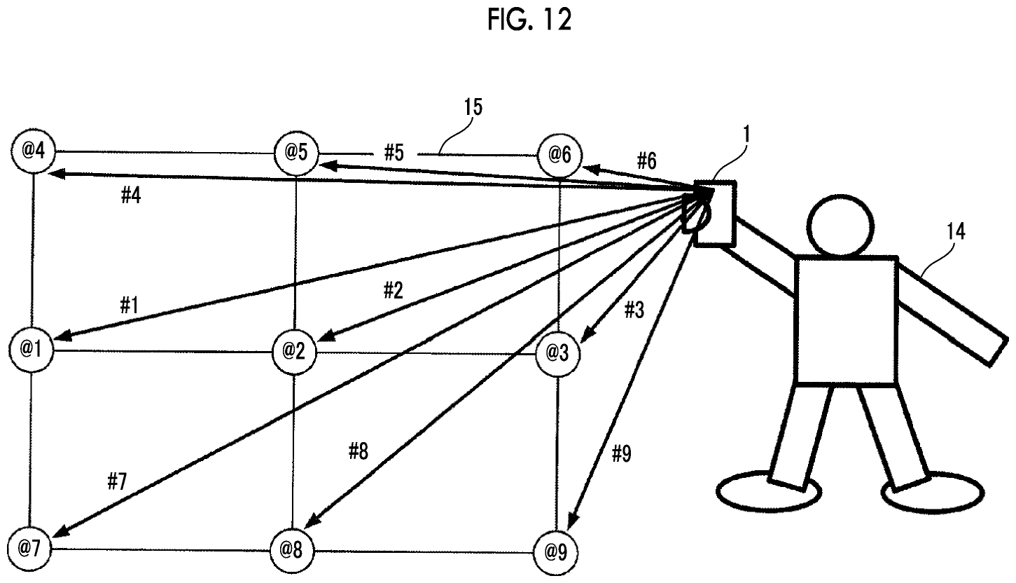

FIG. 12 is a diagram showing a state where light is emitted from the optical measurement apparatus 1. Here, it is assumed that the person 14 holds the optical measurement apparatus 1 in his or her right hand and measures presence or absence of the target object in front of him or her.

For example, light from the LD/S group #1 of the light emitting component 10 in the optical device 30 travels toward a region @1 of the irradiated surface 15 virtually set. Further, the light from the LD/S group #2 travels toward a region @2. In such a manner, light is emitted from the LD/S groups #1 to #9 toward different regions @1 to @9. Then, the light receiving unit 11 receives the reflected light. Then, the processing unit 12 measures the time that elapses until the light is emitted and then the light receiving unit 11 receives the reflected light. Then, it is possible to detect which direction the measurement target object 13 is located in. That is, the optical measurement apparatus 1 is a proximity sensor. Further, the two-dimensional or three-dimensional shape of the measurement target object 13 is measured from the distance to the measurement target object 13.

The method is a surveying method based on a light arrival time, and is called a time-of-flight (TOF) method. In the method, for example, light having a shape of a plurality of pulses may be emitted in order to improve a measurement accuracy. Further, the number of pulses may be increased to improve the measurement accuracy, in a specific direction, for example, in FIG. 12, for the region @2 on the front side. That is, a period for irradiating the region @2 with light may be longer than other periods, and the number of pulses may be increased.

The optical device 30 sequentially emits light in the predetermined direction. Therefore, the optical device 30 has a resolution lower than a resolution in a case where light is emitted simultaneously in multiple directions, but consumes less power. Further, in a case where light is emitted simultaneously in multiple directions, it is necessary to identify the direction in which the reflected light comes by using the light receiving elements in which the light receiving elements are arranged two-dimensionally. In contrast, in the optical measurement apparatus 1 that emits light by sequentially changing the direction, it is not necessary to use a light receiving element in which light receiving elements are arranged in two dimensions, and it suffice to use a light receiving element capable of measuring a change in the intensity of the received light at high speed. Therefore, the configuration of the optical measurement apparatus 1 is simplified.

The light emitting component 10 in the optical device 30 shown in FIG. 10 comprises nine LD/S groups #1 to #9. Then, as shown in FIG. 12, nine regions @1 to @9 of 3×3 are irradiated. Therefore, in a case where increasing the number of regions, the number of LD/S groups to be arranged may be changed. In a case of irradiating 25 regions @1 to @25 of 5×5, 25 LD/S groups may be provided. In addition, 20 areas of 5×4 and 4×5 may be used. Further, the LD/S group is arranged in one dimension, but may be arranged in two dimensions. Further, the irradiated regions do not have to be arranged in a grid pattern. The optical element such as the lens LZ may be set to set the emission direction of light from the laser diode LD of the light emitting component 10 in the optical device 30 so as to irradiate a location to be measured.

As described above, the optical device 30 in the second exemplary embodiment sequentially drives the LD/S groups in the light emitting component 10 along the arrangement so as to irradiate the light in a planar manner. That is, light is emitted into a two-dimensional space through a one-dimensional operation.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A light emitting element comprising:
a substrate;
a light emitting unit that is laminated on the substrate; and
a thyristor that is laminated on the light emitting unit and performs setting so as to cause the light emitting unit to emit light or increase an amount of emitted light by being turned into an ON state, the thyristor having a low resistance layer with a resistance which does not electrically separate the thyristor at a position where a current flows from an electrode being in contact with the thyristor.

2. The light emitting element according to claim 1, wherein a signal for controlling the ON state and an OFF state of the thyristor is supplied to the electrode.

3. The light emitting element according to claim 1, further comprising a supply electrode that supplies a current for light emission to the light emitting unit.

4. The light emitting element according to claim 2, further comprising a supply electrode that supplies a current for light emission to the light emitting unit.

5. The light emitting element according to claim 1, wherein the low resistance layer is a p-type semiconductor layer and has an impurity concentration of 1×10¹⁹/cm³ or more and 1×10²¹/cm³ or less.

6. The light emitting element according to claim 2, wherein the low resistance layer is a p-type semiconductor layer and has an impurity concentration of 1×10¹⁹/cm³ or more and 1×10²¹/cm³ or less.

7. The light emitting element according to claim 3, wherein the low resistance layer is a p-type semiconductor layer and has an impurity concentration of 1×10¹⁹/cm³ or more and 1×10²¹/cm³ or less.

8. The light emitting element according to claim 4, wherein the low resistance layer is a p-type semiconductor layer and has an impurity concentration of 1×10¹⁹/cm³ or more and 1×10²¹/cm³ or less.

9. The light emitting element according to claim 1, wherein the low resistance layer includes an n-type semiconductor layer having an impurity concentration of greater than 1×10¹⁸/cm³.

10. The light emitting element according to claim 2, wherein the low resistance layer includes an n-type semiconductor layer having an impurity concentration of greater than 1×10¹⁸/cm³.

11. The light emitting element according to claim 3, wherein the low resistance layer includes an n-type semiconductor layer having an impurity concentration of greater than 1×10¹⁸/cm³.

12. The light emitting element according to claim 4, wherein the low resistance layer includes an n-type semiconductor layer having an impurity concentration of greater than 1×10¹⁸/cm³.

13. The light emitting element according to claim 9, wherein the n-type semiconductor layer and another layer of the thyristor are laminated via a tunnel junction.

14. A light emitting element array comprising a plurality of light emitting elements according to claim 1,
wherein the thyristor included in each of the plurality of light emitting elements is connected via a connection part, and
the electrode is disposed on the connection part.

15. A light emitting element array comprising a plurality of light emitting elements according to claim 1,
wherein the electrode between the plurality of light emitting elements is shared.

16. The light emitting element array according to claim 14,
wherein a plurality of light emitting element groups each having the plurality of light emitting elements are arranged, and
the thyristor included in the light emitting elements of each light emitting element group of the plurality of light emitting element groups is turned on at different time in each light emitting element group.

17. A light emitting component comprising:
a substrate;
a plurality of light emitting components that are laminated on the substrate;
a plurality of setting thyristors that are each laminated on the plurality of light emitting components and perform setting such that the light emitting components emit light or increase an amount of emitted light by being turned into an ON state; and
a plurality of transfer thyristors that are connected to each of the plurality of the setting thyristors and sequentially transfer the ON state so as to enable the connected setting thyristor to shift to the ON state,
wherein a low resistance layer with a resistance lower than a resistance of a layer through which a current flows from an electrode being in contact with a transfer thyristor is provided at a position where a current flows from an electrode being in contact with the setting thyristor.

18. The light emitting component according to claim 17,
wherein the layer through which the current flows from the electrode being in contact with the transfer thyristor is a semiconductor layer with a higher resistance than the low resistance layer.

19. An optical device comprising:
the light emitting component according to claim 17; and
an optical element that sets a direction or a spread angle of light emitted from each light emitting element group in a plurality of light emitting element groups included in the light emitting component to a predetermined direction or a predetermined spread angle.

20. An optical measurement apparatus comprising:
the optical device according to claim 19;
a light receiving unit that receives reflected light from a target object irradiated with light from the optical device; and
a processing unit that processes information about light received by the light receiving unit to measure a distance from the optical device to the target object or a shape of the target object.
